(19) United States
(12) Patent Application Publication
(10) Pub. No.: US 2006/0267092 A1
(43) Pub. Date: Nov. 30, 2006

(54) High power semiconductor device capable of preventing parasitical bipolar transistor from turning on

(75) Inventors: Kwang-Yeon Jun, Wonmi-Gu (KR); Tea-Sun Lee, Ilsan-gu (KR); Jung-Ho Lee, Tanhyeon-Myeon (KR); Jong-Min Kim, Seoul (KR); Joon-Hyun Kim, Ilsan-Gu (KR)

Correspondence Address: BIRCH STEWART KOLASCH & BIRCH, PO BOX 747, FALLS CHURCH, VA, 22040-0747, US

(73) Assignee: LITE-ON SEMICONDUCTOR CORP.

(21) Appl. No.: 11/300,448

(22) Filed: Dec. 15, 2005

(30) Foreign Application Priority Data
May 31, 2005 (KR) 10-2005-0045860

(51) Int. Cl. H01L 29/76

(52) U.S. Cl. 257/342

(57) ABSTRACT

A high power semiconductor device capable of preventing parasitical bipolar transistor from turning on comprises a first conduction type drain region, a first conduction type epitaxial region formed on the first conduction type drain region, a plurality of second conduction type body regions formed on the surface of the epitaxial region, at least a first conduction type source region formed on the surface of the body regions, a source electrode contact region formed on the surface of the body regions and overlapping the source region and having at least one end longer than one end of the source region, and a plurality of gate electrodes staggered with the source electrode contact region and formed on the body regions and the epitaxial region.

### BACKGROUND OF THE INVENTION

1. Field of the Invention

The present invention relates to a high power semiconductor device and, more particularly, to a high power semiconductor device capable of enhancing the ruggedness under high current densities (di/dt) and effectively preventing the parasitical bipolar transistor from turning on when a MOSFET turns off from the on state.

2. Description of Related Art

High power devices require the characteristics of high breakdown voltage, low on-resistance, high switching speed, and low switching loss. Therefore, today's manufacturers utilizes MOSFET high power devices with an input impedance lower than that of bipolar transistors, a high switching speed, and a good safety operation range.

As shown in FIG. 1A, a prior art high power MOSFET comprises an n-type semiconductor substrate (sub) functioning as a drain, an epitaxial layer (EL) disposed on the semiconductor substrate, a p-type body region (PB) disposed on the surface of the epitaxial layer, a gate (G) disposed on the epitaxial layer and the body region, and an n⁺-type source region disposed on the surface of the body region at two ends of the gate. In FIG. 1A, the symbol ‘IL’ represents an insulating layer such as phosphor silicate glass (PSG).

In order to improve the breakdown voltage and on-resistance of a high power MOSFET, it is necessary to provide an epitaxial layer on the semiconductor substrate by all manner of means. Therefore, a parasitical bipolar transistor will exist in the high power MOSFET. For instance, the n⁺-type source region, the p-type body region and the n-type epitaxial layer respectively function as an emitter, a base and a collector to form an npn parasitical bipolar transistor. FIG. 1B is a circuit diagram of the high power MOSFET device shown in FIG. 1A and a parasitical bipolar transistor formed therein.

When the parasitical bipolar transistor turns on, a latch phenomenon will arise to increase the possibility of device breakdown. Therefore, in the design of a high power MOSFET, it is necessary to prevent the parasitical bipolar transistor from turning on.

When a high power MOSFET is switched from the on state to the off state, the channel below the gate will be closed so that the current flow through the channel is forbidden. All the current will flow toward the internal diode (D1) of the MOSFET. The drain (D) of a power MOSFET is applied with an anode voltage, and a reverse voltage across the internal diode formed between the n-type epitaxial layer (EL) and the p-type body region will increase. When the gate voltage is cut off, a displacement current will be generated and flows toward the p-type body region (PB) via the depletion region of the internal diode. At this time, a voltage variation will be generated according to the resistance of the p-type body region below the source region (i.e., the body distribution resistance, R_{be}), and the voltage variation is high enough (e.g., higher than 0.7V) to turn on the npn parasitical bipolar transistor, hence causing the latch phenomenon. If the voltage variation determined by the product of the current and the body distribution resistance is smaller than a predetermined value, the on-phenomenon of the npn parasitical bipolar transistor can be avoided. With the increase of the current density, the on-phenomenon of the npn parasitical bipolar transistor will still happen if the current exceeds a predetermined value. Moreover, the current-increase characteristic of the npn parasitical bipolar transistor will bring about a large increase of current to finally break down the MOSFET.

The problems of the prior art high power MOSFET will be illustrated more specifically below with reference to FIGS. 2A to 2C, FIGS. 3A to 3D, and FIG. 4.

FIGS. 2A to 2C show cell structures disposed at the corner, edge, and gate pad of a prior art high power MOSFET chip, respectively. FIG. 3A is a cross-sectional view along a line A-A′ in FIG. 2A or a line J-J′ in FIG. 2B. FIG. 3B is a cross-sectional view along a line B-B′ in FIG. 2A, a line I-I′ in FIG. 2B, or a line K-K′ in FIG. 2C. FIG. 3C is a cross-sectional view along a line C-C′ in FIG. 2A. FIG. 3D is a cross-sectional view along a line D-D′ in FIG. 2A.

As shown in FIG. 3A, the current flowing out from the lower end region of a RING region (not shown) and a scribe lane of a chip will flow inwards from the left side. The n⁺-type source region always contacts the current earlier than the source electrode contact region (briefly called the contact region (CT) afterwards). In other words, under normal situations, the current from the RING region and the scribe lane passes the diode formed by the n-type epitaxial layer and the p-type body region and then flows out via the contact region. Because the current is blocked by the n⁺-type source region, it will flow through the lower face of the n⁺-type source region. Until the current reaches the region where the body region and the contact region joins as shown in FIG. 3A, it then flows out via the contact region. Based on the characteristic of the prior art high power MOSFET, the current has to pass the body distribution resistance region where the body region and the contact region joins. As shown in FIG. 3A, in the region where the body region and the contact region do not join, the channel through which the current can flow out to the contact region is blocked. The current keeps flowing in the p-type body region. As shown in FIGS. 3B and 3C, after the current reaches the region where the body region and the contact region joins, it will flow out via the contact region. As shown in FIG. 3A, under the situation that the channel through which the current can flow out to the contact region is blocked, the body distribution resistance will lead to a voltage variation to substantially increase the possibility of the on-phenomenon of the npn parasitical bipolar transistor.

FIG. 4 is a diagram showing the arrangement of the source regions and the contact regions and the current direction of FIG. 2A. FIG. 4 primarily shows the current flowing toward the source region under the situation that the MOSFET turns off. The current (I1) encounters the contact region earlier than the source region will easily flow out via the contact region, hence not causing the on-phenomenon of the parasitical bipolar transistor. But before the current (I2) flowing in the lower end portion of the n⁺-type source region flows out via the contact region, it first passes the body distribution resistance region at the lower end portion of the source region, hence becoming the primary reason of the voltage variation that causes the on-phenomenon of the parasitical bipolar transistor.

After the parasitical bipolar transistor turns on, the current-increase characteristic of the bipolar transistor will increase the current density. The device will break down at the region where the current density is the highest. This situation not only can occur at the chip corner, but also can occur at the chip edge or the gate pad of the chip.

Controlling the current increase per unit time (i.e., the current ramp rate, di/dt) can prevent the parasitical bipolar transistor from turning on. That is, when the current ramp rate is high, the on-phenomenon of the parasitical bipolar transistor may arise to increase the possibility of device breakdown. In order to reduce the current ramp rate, one can increase the concentration of the p-type impurities implanted into the lower end portion of the n⁺-type source region to decrease the body distribution resistance so as to control the on-phenomenon of the parasitical bipolar transistor. But this method will also influence the concentration of the body region beside the n⁺-type source region to affect the on-voltage of the gate. The concentration of the n⁺-type source region will also be reduced to probably bring about an increase of the channel resistance and finally result in abnormal operations of the device.

### SUMMARY OF THE INVENTION

An object of the present invention is to provide a high power semiconductor device capable of effectively preventing parasitical bipolar transistor from turning on.

The present invention provides a high power semiconductor device capable of preventing parasitical bipolar transistor from turning on. The high power semiconductor device comprises a first conduction type drain region, a first conduction type epitaxial region formed on the first conduction type drain region, a plurality of second conduction type body regions formed on the surface of the epitaxial region, at least a first conduction type source region formed on the surface of the body regions, a source electrode contact region formed on the surface of the body regions and overlapping the source region and having at least one end longer than one end of the source region, and a plurality of gate electrodes staggered with the source electrode contact region and formed on the body regions and the epitaxial region.

### BRIEF DESCRIPTION OF THE DRAWINGS

The various objects and advantages of the present invention will be more readily understood from the following detailed description when read in conjunction with the appended drawing, in which:

FIG. 1A is a cross-sectional view of a prior art high power MOSFET device;

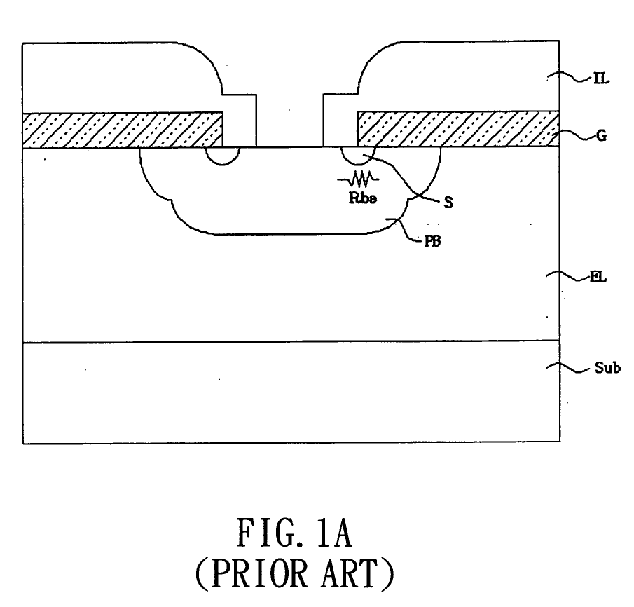

FIG. 1B is a circuit diagram of the high power MOSFET device shown in FIG. 1A and a parasitical bipolar transistor formed therein;

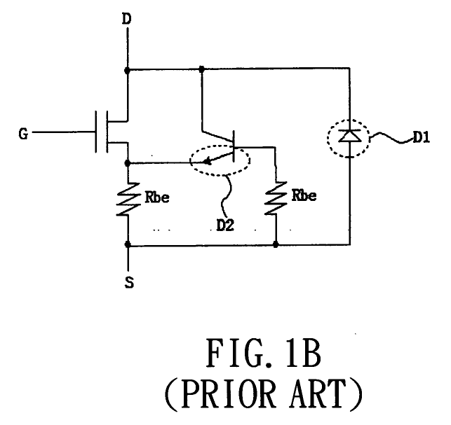

FIGS. 2A to 2C show cell structures disposed at the corner, edge, and gate pad of a prior art high power MOSFET chip, respectively;

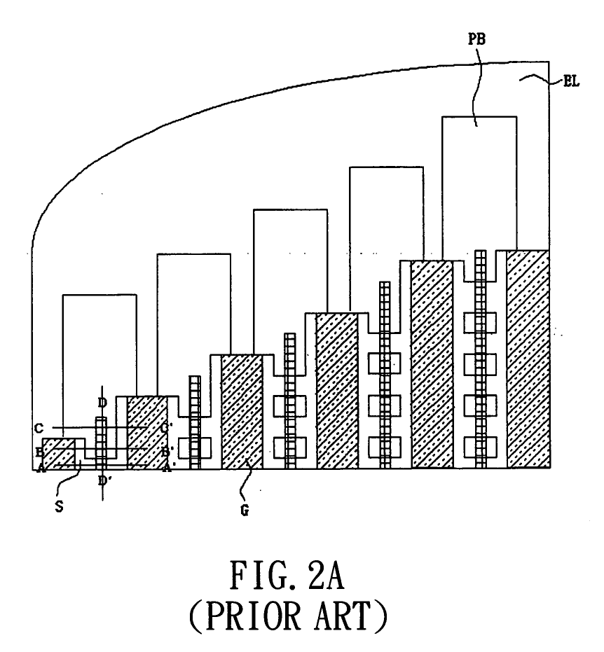

FIG. 3A is a cross-sectional view along a line A-A′ in FIG. 2A and a line J-J′ in FIG. 2B;

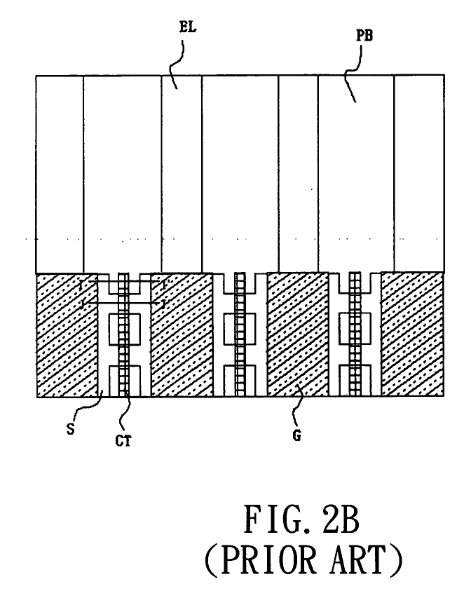

FIG. 3B is a cross-sectional view along a line B-B′ in FIG. 2A, a line I-I′ in FIG. 2B, and a line K-K′ in FIG. 2C;

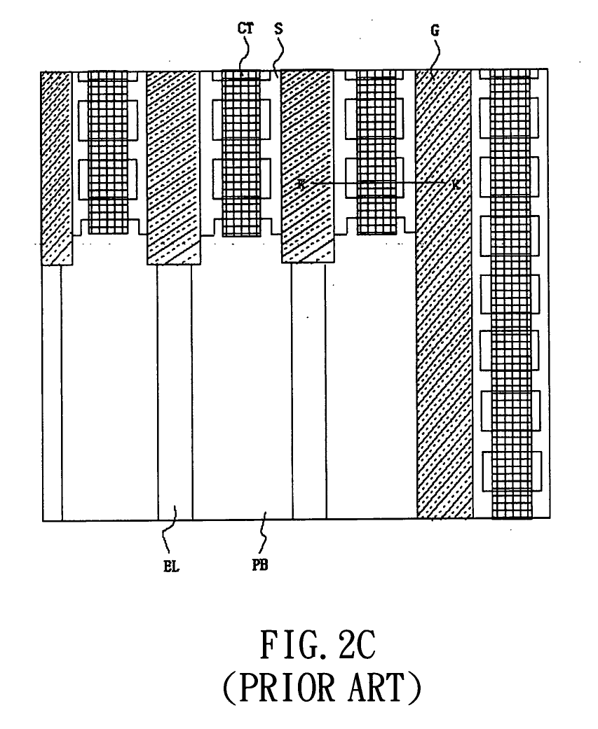

FIG. 3C is a cross-sectional view along a line C-C′ in FIG. 2A;

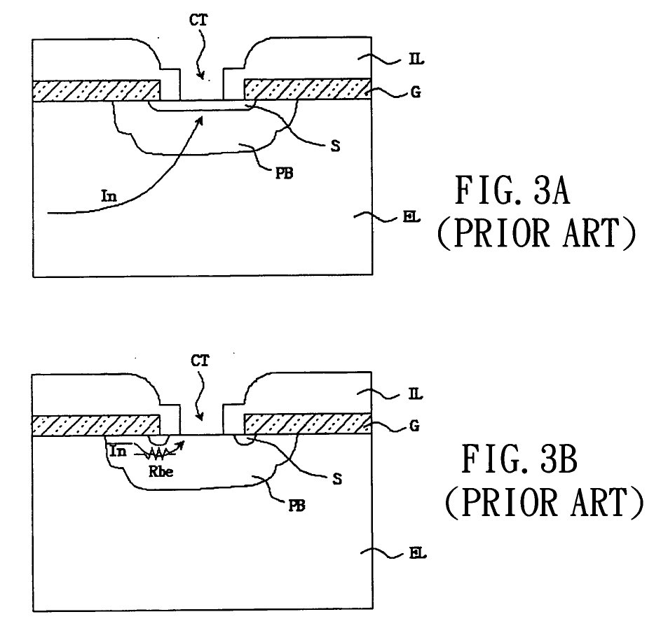

FIG. 3D is a cross-sectional view along a line D-D′ in FIG. 2A;

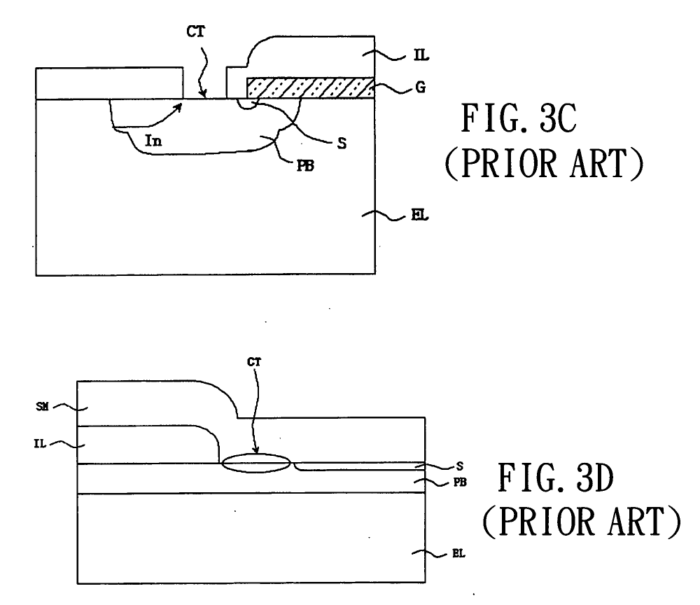

FIG. 4 is a diagram showing the arrangement of the source regions and the contact regions and the current direction of FIG. 2A;

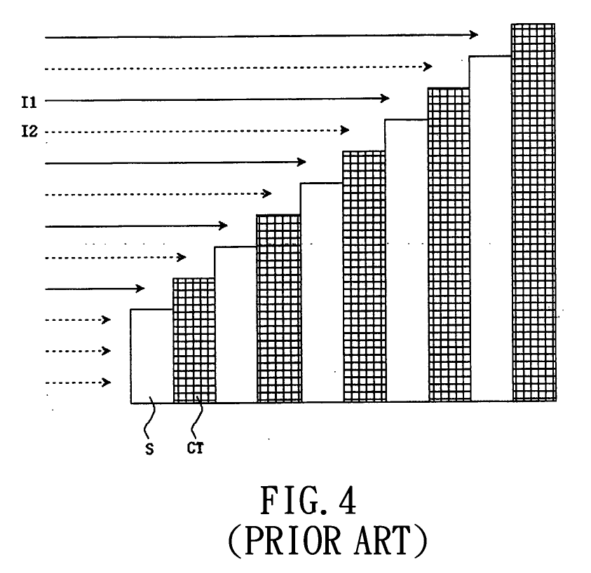

FIG. 5 is a design diagram of a MOSFET cell according to an embodiment of the present invention;

FIG. 6 is a plan view of a MOSFET chip structure of the present invention;

FIG. 7A is a design diagram of a MOSFET cell at the chip corner of FIG. 6;

FIGS. 7B and 7C are cross-sectional views along a line E-E′ and a line F-F′ in FIG. 7A, respectively;

FIG. 8A a design diagram of a MOSFET cell at the chip edge of FIG. 6;

FIG. 8B is a diagram showing the arrangement of the gate metal electrode and the source metal electrode shown in FIG. 8A;

FIG. 9A is a design diagram of a MOSFET cell around the gate pad of the chip of FIG. 6;

FIG. 9B is a diagram showing the arrangement of the gate metal electrode and the source metal electrode shown in FIG. 9A; and

FIG. 10 is a diagram showing the arrangement of the source regions and the contact regions and the current direction of FIG. 7A.

### DETAILED DESCRIPTION OF THE PREFERRED EMBODIMENTS

The present invention proposes a high power semiconductor device, which can be an n-channel MOSFET (in which the first conduction type is n-type, and the second conduction type is p-type) or a p-channel MOSFET (in which the first conduction type is p-type, and the second conduction type is n-type).

According to an embodiment of the present invention, the high power semiconductor device comprises a first conduction type drain region, a first conduction type epitaxial region formed on the first conduction type drain region, a plurality of second conduction type body regions formed on the surface of the epitaxial region, at least a first conduction type source region formed on the surface of the body regions, a source electrode contact region formed on the surface of the body regions and overlapping the source region and having at least one end longer than one end of the source region, and a plurality of gate electrodes staggered with the source electrode contact region and formed on the body regions and the epitaxial region.

According to another embodiment of the present invention, the high power semiconductor device has a scribe lane and a RING region formed within the scribe lane. The high power semiconductor device comprises a first conduction type drain region enclosed by the RING region, a first conduction type epitaxial region formed on the first conduction type drain region, a plurality of second conduction type body regions formed on a surface of the epitaxial region, at least a first conduction type source region formed on a surface of the body regions, a source electrode contact region formed on the surface of the body regions and overlapping the source region and contacting a current incoming from a lower end of the scribe lane earlier than the source region, and a plurality of gate electrodes formed on the body regions and the epitaxial region and staggered with the source electrode contact region.

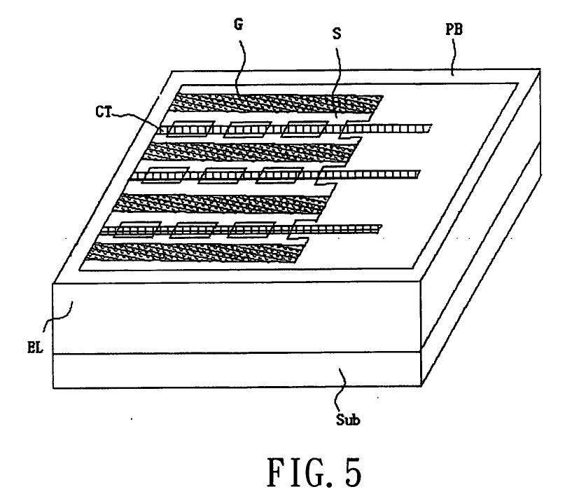

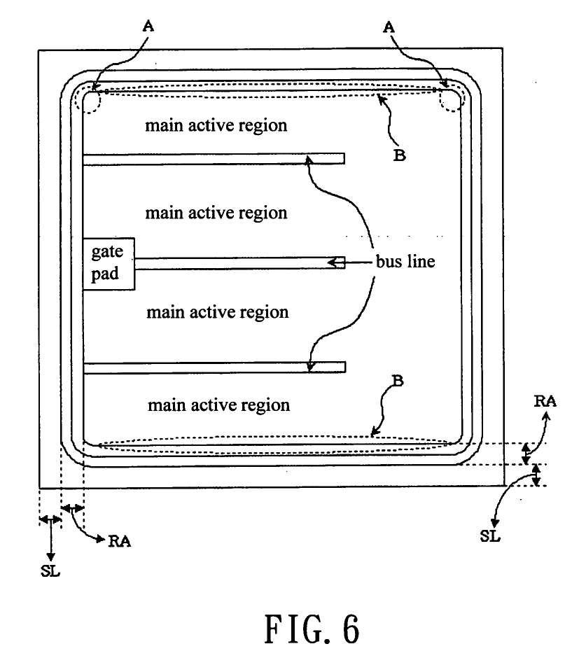

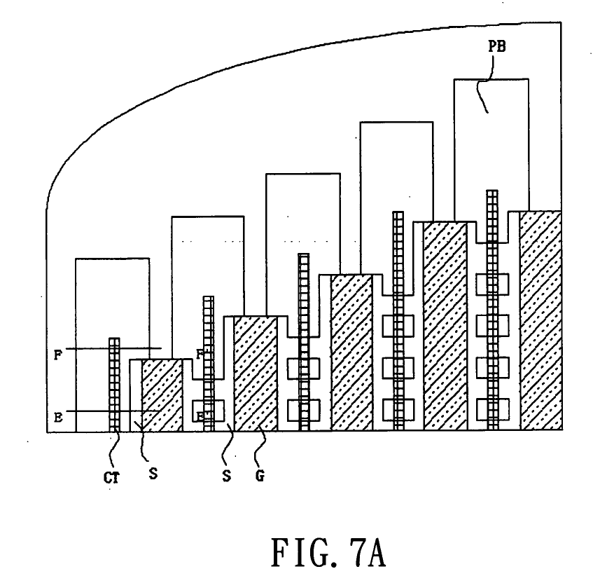

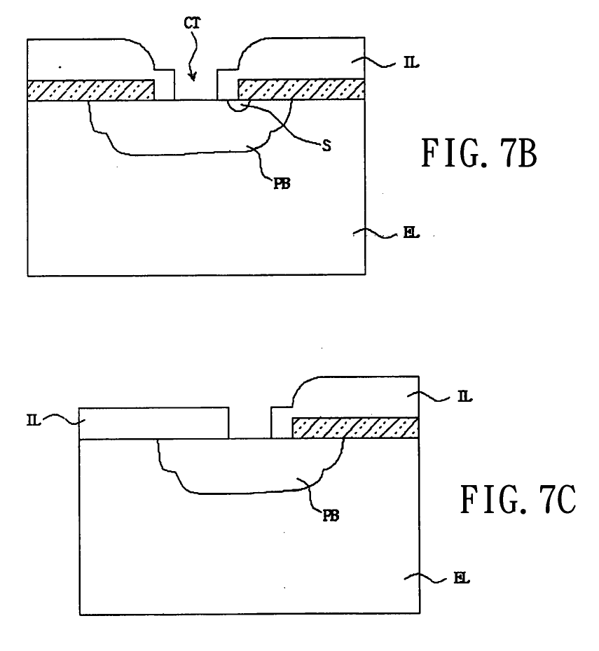

The MOSFET of the present invention will be illustrated more in detail below with reference to FIG. 5, FIG. 6, FIGS. 7A to 7C, FIGS. 8A to 8B, FIG. 9A to 9B, and FIG. 10.

As shown in FIG. 5, the present invention provides a high power semiconductor device comprises an n-type semiconductor substrate (sub) functioning as a drain, an n-type epitaxial layer (EL) formed on the semiconductor substrate, a plurality of p-type body regions formed on the surface of the epitaxial layer (EL), a trapezoid n⁺-type source region formed on the surface of the p-type body regions, a plurality of stripe-shaped source (S) electrode contact regions (briefly called contact regions, CT) formed between the p-type body regions and the n⁺-type source region and having one end longer than one end of the n-type source region, and a plurality of stripe-shaped gate electrodes formed on the body regions and the epitaxial region and staggered with the source electrode contact regions.

In the high power MOSFET of the present invention, the n⁺-type source region, the p-type body region, and the n-type epitaxial layer respectively function as an emitter, a base and a collector, hence forming an npn parasitical bipolar transistor.

As shown in FIG. 6, the MOSFET chip structure comprises a RING region (RA), a gate pad, and bus lines. The RING region (RA) further comprises a scribe lane, several main active areas, and an impurity region enclosing the main active areas. The gate pad is disposed at the center of the surface of the main active areas. The bus lines crosscut the main active areas. The high power MOSFET structure shown in FIG. 5 is included on the main active areas.

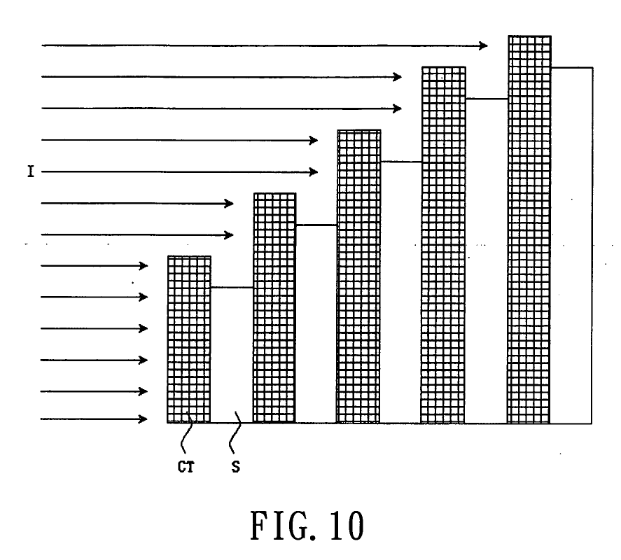

As shown in FIG. 7A, because one end of the contact region is longer than one end of the n⁺-type source region, under the situation that the MOSFET is in the off state, the current (I) incoming from the lower end portion of the scribe lane and the RING region directly flows into the contact region instead of via the n⁺-type source region, as shown in FIG. 10. In other words, the current (I) won't pass the p-type body region (i.e., the body distribution resistance (R_{be}) region) at the lower end of the n⁺-type source region, but directly flows out via the contact region. Moreover, by comparing the cross-sections along the line E-E′ and F-F′ in FIG. 7A with FIGS. 7B and 7C, the structure of FIG. 7C is superior to FIG. 7B in terms of current ramp rate (di/dt). However, the smaller the area of the n⁺-type source region, the higher the drain-source resistance. In design, it is therefore necessary to make a trade-off between the current ramp rate (di/dt) characteristic and the drain-source resistance by all manner of means.

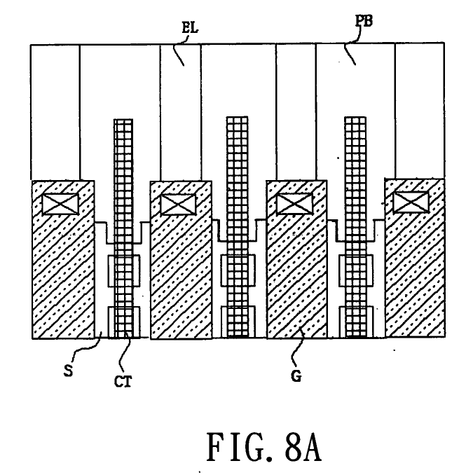

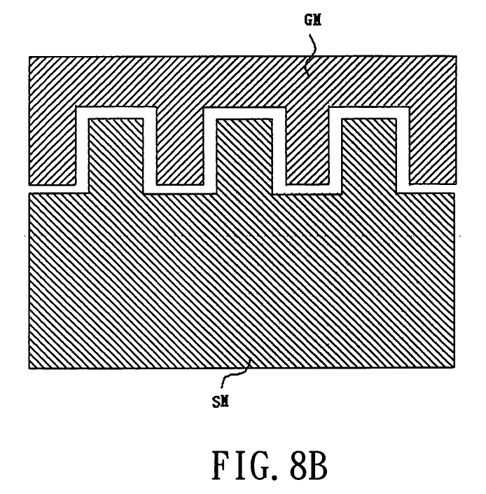

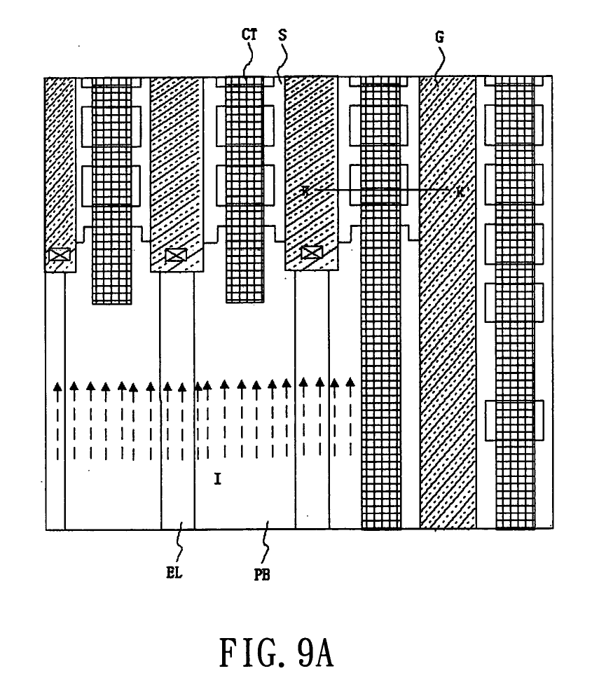

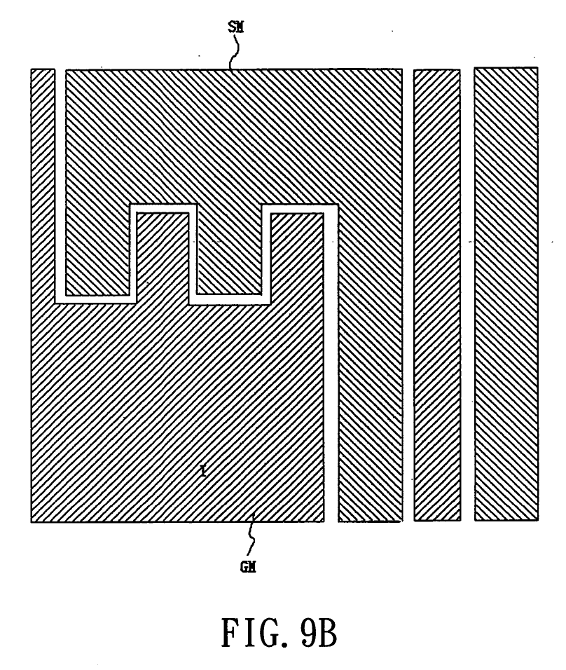

As shown in FIGS. 8A and 9A, one end of the contact region is longer than one end of the n⁺-type source region on the chip edge and the gate pad of a high power MOSFET cell. That is, one end of the contact region is closer to the cell edge than one end of the n⁺-type source region. The contact region between the p-type body region and the contact region will therefore become larger. Under the situation that the MOSFET is in the off state, the current flowing toward the source region will first flow into the contact region. Although the area of the n⁺-type source region at the cell edge becomes smaller, the influence is slight.

FIG. 8B is a diagram showing the arrangement of the gate metal electrode and the source metal electrode shown in FIG. 8A. FIG. 9B is a diagram showing the arrangement of the gate metal electrode (GM) and the source metal electrode (SM) shown in FIG. 9A. As shown in FIG. 8B, the GM and the SM have finger structures and can thus be joined together. In other words, depressed portions and raised portions of the lumpy GM can be disposed on raised portions and depressed portions of the lumpy SM, respectively.

To sum up, the present invention provides a structure in which one end of the contact region is longer than one end of the n⁺-type source region in each active cell of a high power MOSFET to enhance the current ramp rate (di/dt) of the high power MOSFET. That is, under the situation that the MOSFET is in the off state, the current flowing toward the diode direction will be prevented from flowing into the body region (the body distribution resistance region) at the lower end of the source region, thereby preventing the parasitical bipolar transistor from turning on.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

What is claimed is:

1. A high power semiconductor device capable of preventing parasitical bipolar transistor from turning on comprising:
a first conduction type drain region;
a first conduction type epitaxial region formed on said first conduction type drain region;
a plurality of second conduction type body regions formed on a surface of said epitaxial region;
at least a first conduction type source region formed on a surface of said body regions;
a source electrode contact region formed on the surface of said body regions and overlapping said source region and having at least one end longer than one end of said source region; and
a plurality of gate electrodes formed on said body regions and said epitaxial region and staggered with said source electrode contact region.

2. The high power semiconductor device as claimed in claim 1, wherein said high power semiconductor device is an n-channel MOSFET, and said first conduction type is n-type and said second conduction type is p-type.

3. The high power semiconductor device as claimed in claim 1, wherein said high power semiconductor device is a p-channel MOSFET, and said first conduction type is p-type and said second conduction type is n-type.

4. The high power semiconductor device as claimed in claim 1, further comprising a plurality of cell structures, one end of said source electrode contact region in each said cell structure is closer to an edge of said cell structure than said source region.

5. The high power semiconductor device as claimed in claim 1, wherein said body region is stripe-shaped.

6. The high power semiconductor device as claimed in claim 4, wherein said gate region is stripe-shaped.

7. The high power semiconductor device as claimed in claim 1, further comprising a lumpy source electrode and a lumpy gate electrode, wherein said lumpy source electrode is connected to said source region via said source electrode contact region and is composed of depressed portions and raised portions, and said lumpy gate electrode is connected to said gate region and has depressed portions and raised portions that can be disposed on said raised portions and said depressed portions of said source region, respectively.

8. A high power semiconductor device capable of preventing parasitical bipolar transistor from turning on, said high power semiconductor device having a scribe lane and a RING region formed within said scribe lane, said high power semiconductor device comprising:
a first conduction type drain region enclosed by said RING region;
a first conduction type epitaxial region formed on said first conduction type drain region;
a plurality of second conduction type body regions formed on a surface of said epitaxial region;
at least a first conduction type source region formed on a surface of said body regions;
a source electrode contact region formed on the surface of said body regions and overlapping said source region and contacting a current incoming from a lower end of said scribe lane earlier than said source region; and
a plurality of gate electrodes formed on said body regions and said epitaxial region and staggered with said source electrode contact region.

9. The high power semiconductor device as claimed in claim 8, wherein said high power semiconductor device is an n-channel MOSFET, and said first conduction type is n-type and said second conduction type is p-type.

10. The high power semiconductor device as claimed in claim 8, wherein said high power semiconductor device is a p-channel MOSFET, and said first conduction type is p-type and said second conduction type is n-type.

11. The high power semiconductor device as claimed in claim 8, wherein said source electrode contact region contacts a current incoming from a lower end of said scribe lane earlier than said source region.

12. The high power semiconductor device as claimed in claim 8, further comprising a plurality of cell structures, one end of said source electrode contact region in each said cell structure is closer to an edge of said cell structure than said source region.

13. The high power semiconductor device as claimed in claim 8, wherein said body region is stripe-shaped.

14. The high power semiconductor device as claimed in claim 8, wherein said gate region is stripe-shaped.

15. The high power semiconductor device as claimed in claim 8, further comprising a lumpy source electrode and a lumpy gate electrode, wherein said lumpy source electrode is connected to said source region via said source electrode contact region and is composed of depressed portions and raised portions, and said lumpy gate electrode is connected to said gate region and has depressed portions and raised portions that can be disposed on said raised portions and said depressed portions of said source region, respectively.
